(19) United States
(12) Patent Application Publication
(10) Pub. No.: US 2025/0329361 A1
(43) Pub. Date: Oct. 23, 2025

(54) SIGNAL DELAY CONTROL WITH INVERTED FEEDBACK

(71) Applicant: Micron Technology, Inc., Boise, ID (US)

(72) Inventors: Timothy M. Hollis, Meridian, ID (US); Chulkyu Lee, Meridian, ID (US); Jennifer E. Taylor, Boise, ID (US)

(21) Appl. No.: 19/040,661

(22) Filed: Jan. 29, 2025

Related U.S. Application Data
(60) Provisional application No. 63/636,520, filed on Apr. 19, 2024.

(51) Int. Cl. G11C 7/22; H03K 5/134

(52) U.S. Cl. CPC G11C 7/222; H03K 5/134

(57) ABSTRACT

Methods, systems, and devices for signal delay control with inverted feedback are described. A system may include a delay circuit that is configured with a chain of delay elements along a forward path of the delay circuit and one or more feedback elements that provide electrical feedback to the forward path. Feedback elements may be or include feedback inverters, such as tri-state inverters, with one or more inputs that are operable to control a signal strength at an output of the feedback inverter. A feedback signal may contend with a signal along the forward path, which may reduce a voltage level associated with the forward signal. By controlling the strength of the feedback signal, the delay circuit may be able to dynamically adjust a delay of the forward signal.

### CROSS REFERENCE

The present Application for Patent claims priority to U.S. Patent Application No. 63/636,520 by Hollis et al., entitled “SIGNAL DELAY CONTROL WITH INVERTED FEEDBACK,” filed Apr. 19, 2024, which is assigned to the assignee hereof, and which is expressly incorporated by reference in its entirety herein.

### TECHNICAL FIELD

The following relates to one or more systems for memory, including signal delay control with inverted feedback.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports signal delay control with inverted feedback in accordance with examples as disclosed herein.

FIG. 2 shows an example of a circuit that supports signal delay control with inverted feedback in accordance with examples as disclosed herein.

FIG. 3 shows an example of timing diagrams that support signal delay control with inverted feedback in accordance with examples as disclosed herein.

FIG. 4 shows a flowchart illustrating a method or methods that support signal delay control with inverted feedback in accordance with examples as disclosed herein.

### DETAILED DESCRIPTION

Some systems (e.g., semiconductor systems, memory systems, host systems, processor systems) may include circuitry (e.g., delay circuitry, a delay chain) that is associated with delaying a timing of a signal, such as a timing signal, a data signal, a control signal, a command signal, a memory access signal, or other types of signals (e.g., delaying rising edges, delaying falling edges, adjusting signal timing relative to a latching event). In some cases, circuit elements (e.g., capacitive circuit elements) used to generate a delayed output signal may be associated with reduced bandwidth capabilities (e.g., due to reducing a slew rate of the input signal, due to reduced edge-rates) or may be susceptible to signal fluctuations (e.g., jitter). Such effects may degrade signal integrity and may constrain bandwidth of the system (e.g., processing speed, memory access speed, throughput). Additionally, some systems (e.g., some delay circuits) may not support configurable control of a delay along a signal path. For instance, a delay (e.g., a time value of the delay) may be preconfigured based on physical characteristics (e.g., physical components) of a system, and the system may not support dynamically adapting delay circuitry to support various applications, manufacturing characteristics, or operating characteristics (e.g., operating speed, operating frequency, operating temperature, operating voltage), among other limitations.

In accordance with one or more techniques described herein, a system may include a delay circuit that is configured with a chain of delay elements (e.g., a sequence of delay elements, serially connected delay elements) along a forward path of the delay circuit and one or more feedback elements that provide electrical feedback (e.g., inverted feedback, negative feedback) to the forward path. In some examples, one or more feedback elements may be or include feedback inverters, such as tri-state inverters, with one or more inputs (e.g., an analog input, a digital input) that are operable to control a signal strength at an output of the feedback inverter. In some examples, delay elements along the forward path may be implemented as inverters (e.g., forward path inverters), and one or more feedback elements may provide a feedback signal across an even quantity (e.g., two) of the forward path inverters. For example, a feedback inverter may couple an output of a first inverter along the forward path to an input of a second inverter that precedes (e.g., immediately precedes) the first inverter along the forward path. The feedback signal may contend with (e.g., counteract, oppose, suppress) a signal on the forward path (e.g., a voltage of a forward signal), which may reduce (e.g., compress, counteract) a voltage level (e.g., a voltage range, a voltage magnitude) associated with the forward signal. Based on the reduced voltage level, the forward signal may transition from one state to another (e.g., from a high voltage state to a low voltage state, from a low voltage state to a high voltage state, for a falling edge, for a rising edge) more quickly, such as for a given slew rate between signal states, which may reduce a delay duration associated with the delay element. In some examples, a feedback element, such as a feedback inverter, may be operable to control a strength of a feedback signal based on biasing a first input (e.g., a header gate) of the feedback element with a first voltage (e.g., a header input voltage) and biasing a second input (e.g., a footer gate) of the feedback element with a second voltage (e.g., a footer input voltage). Thus, by controlling the strength of the feedback signal, the delay circuit may be able to dynamically adjust (e.g., tune, modulate) a delay of the forward signal over a relatively large range. Accordingly, the delay circuitry described herein may be associated with improved signal integrity, relatively higher bandwidth, and relatively flexible timing, among other benefits.

In addition to applicability in memory systems as described herein, techniques for signal delay control with inverted feedback may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving flexibility for adjusting delays of signals with relatively less impact to processing bandwidth, which may decrease processing or latency times, improve response times, or otherwise improve user experience, among other benefits.

Features of the disclosure are illustrated and described in the context of systems. Features of the disclosure are further illustrated and described in the context of circuits, timing diagrams, block diagrams, and flowcharts.

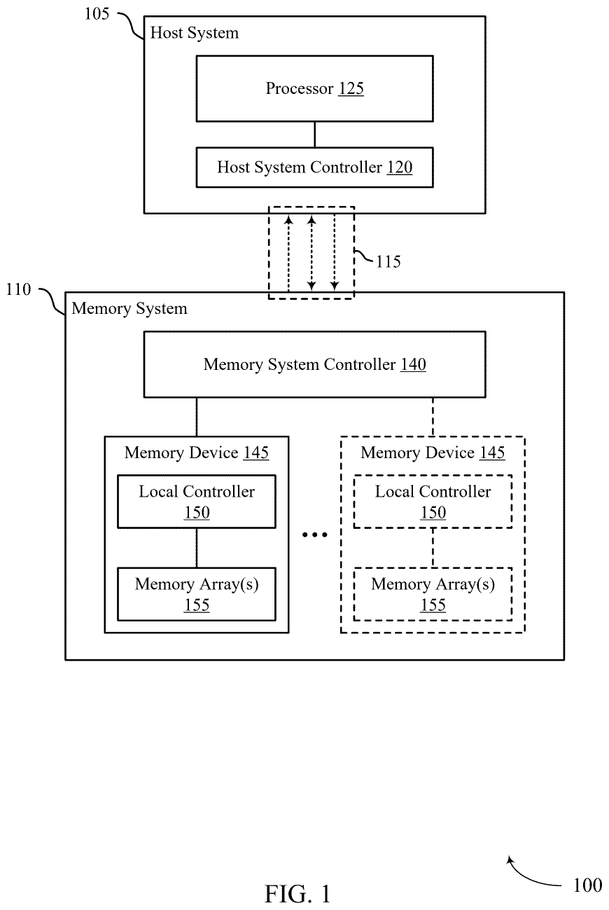

FIG. 1 illustrates an example of a system 100 that supports signal delay control with inverted feedback in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

One or more components of a system 100, among other electronic systems, systems may include circuitry (e.g., delay circuitry, a delay chain) that is associated with delaying a timing of a signal, such as a timing signal, a data signal, a control signal, a command signal, a memory access signal, or other types of signals (e.g., delaying rising edges, delaying falling edges, adjusting signal timing relative to a latching event). For example, a memory system 110 (e.g., a memory system controller 140, a memory device 145, a local controller) may include delay circuitry to delay clock signaling (e.g., generated at an oscillator of the memory system 110, clock signaling received over one or more channels 115 from a host system 105), which may be used for initiating various operations of the memory system 110 (e.g., access operations, data transfer operations, communication operations, multiplexing operations). Additionally, or alternatively, a host system 105 (e.g., a processor 125, a host system controller 120) or a memory system 110 (e.g., a memory system controller 140, a memory device 145, a local controller 150) may include delay circuitry to adjust signal timing (e.g., of clock signals, of data signals, of control signals, of command signals) relative to a latching event, such as a latching to initiate a data processing operation (e.g., to perform a processing operation), a latching to initiate a data communication operation (e.g., to latch a received signal), a latching to initiate an access operation (e.g., to access a memory array 155), or others. For example, a host system 105, a memory system, or both may implement delay circuitry for training of channels 115 (e.g., for data channel and data channel strobe training, such as DQ-DQS training, for decision feedback equalization (DFE) tap training, for phase timing training). Although these represent some examples for implementing delay circuitry at one or more components of a system, the described techniques may be implemented in other applications for delaying an output signal relative to an input signal.

In some cases, circuit elements (e.g., capacitive circuit elements) used to generate a delayed output signal may be associated with reduced bandwidth capabilities (e.g., due to reducing a slew rate of the input signal, due to reduced edge-rates) or may be susceptible to signal fluctuations (e.g., jitter). Such effects may degrade signal integrity and may constrain bandwidth (e.g., processing speed, memory access speed, throughput). Additionally, some systems (e.g., some delay circuits) may not support configurable control of a delay along a signal path. For instance, a delay (e.g., a time value of the delay) may be preconfigured based on physical characteristics (e.g., physical components) of a system, and the system may not support dynamically adapting delay circuitry to support various applications, manufacturing characteristics, or operating characteristics (e.g., operating speed, operating frequency, operating temperature, operating voltage), among other limitations.

In accordance with one or more techniques described herein, one or more components of a system 100 (e.g., a host system 105, a processor 125, a host system controller 120, a memory system 110, a memory system controller 140, a memory device 145, a local controller 150), among other electrical components, may include a delay circuit that is configured with a chain of delay elements (e.g., a sequence of delay elements, serially connected delay elements) along a forward path of the delay circuit and one or more feedback elements that provide electrical feedback (e.g., inverted feedback, negative feedback) to the forward path. In some examples, one or more feedback elements may be or include feedback inverters, such as tri-state inverters, with one or more inputs (e.g., an analog input, a digital input) that are operable to control a signal strength at an output of the feedback inverter. In some examples, delay elements along the forward path may be implemented as inverters (e.g., forward path inverters), and one or more feedback elements may provide a feedback signal across an even quantity (e.g., two) of the forward path inverters. For example, a feedback inverter may couple an output of a first inverter along the forward path to an input of a second inverter that precedes (e.g., immediately precedes) the first inverter along the forward path. The feedback signal may contend with (e.g., counteract, oppose, suppress) a signal on the forward path (e.g., a voltage of a forward signal), which may reduce (e.g., compress, counteract) a voltage level (e.g., a voltage range, a voltage magnitude) associated with the forward signal. Based on the reduced voltage level, the forward signal may transition from one state to another (e.g., from a high voltage state to a low voltage state, from a low voltage state to a high voltage state, for a falling edge, for a rising edge) more quickly, such as for a given slew rate between signal states, which may reduce a delay duration associated with the delay element. In some examples, a feedback element, such as a feedback inverter, may be operable to control a strength of a feedback signal based on biasing a first input (e.g., a header gate) of the feedback element with a first voltage (e.g., a header input voltage) and biasing a second input (e.g., a footer gate) of the feedback element with a second voltage (e.g., a footer input voltage). Thus, by controlling the strength of the feedback signal, the delay circuit may be able to dynamically adjust (e.g., tune, modulate) a delay of the forward signal over a relatively large range. Accordingly, the delay circuitry described herein may support improved signal integrity, relatively higher bandwidth, and relatively flexible timing, among other benefits, to one or more components of a system 100, among other implementations.

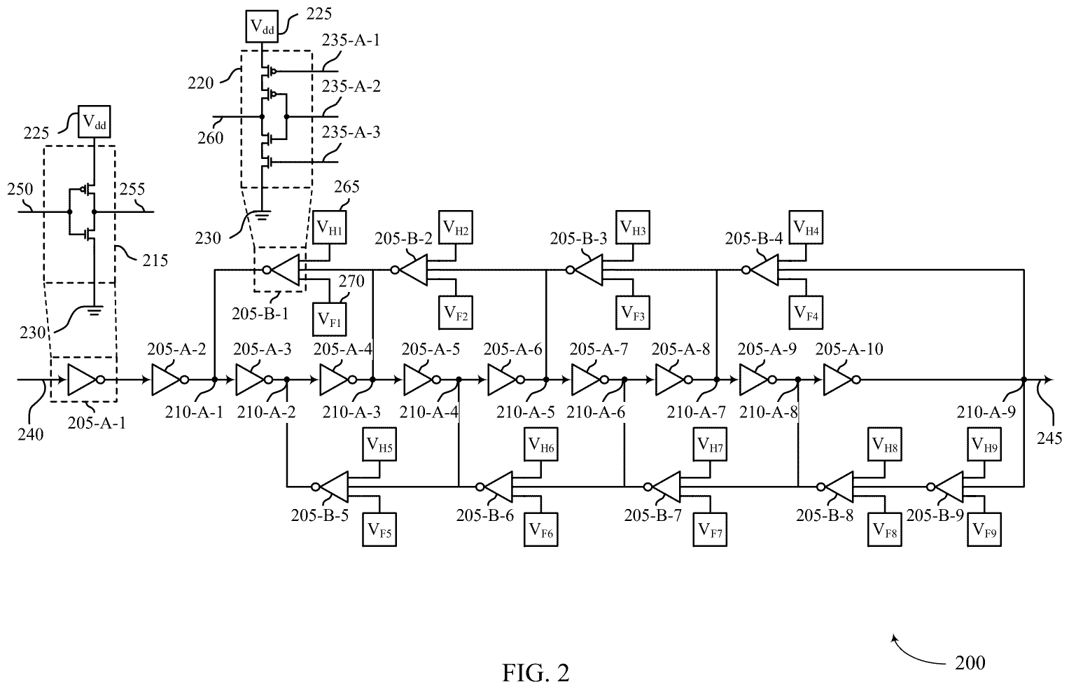

FIG. 2 shows an example of a circuit 200 (e.g., a delay circuit, a delay chain) that supports signal delay control with inverted feedback in accordance with examples as disclosed herein. A circuit 200 may include an input 240 (e.g., an input node, an input terminal) and an output 245 (e.g., an output node, an output terminal), and may be configured to output (e.g., generate) a second signal at the output 245 (e.g., an output signal, a delayed signal, a second timing signal) that has a delay relative to a first signal (e.g., an input signal) received at the input 240.

Any quantity of one or more instances of the circuit 200 may be included in an electronic device (e.g., a host system 105, a processor 125, a host system controller 120, a memory system 110, a memory system controller 140, a memory device 145, a local controller 150, among other electronic devices), with each instance of the circuit 200 configured to generate an output signal at an output 245 having a respective delay relative to an input signal at an input 240. For example, a circuit 200 may be implemented for delaying a timing signal, a data signal, a control signal, a command signal, a memory access signal, or other types of signals (e.g., delaying rising edges, delaying falling edges, adjusting signal timing relative to a latching event). For example, a memory system 110 (e.g., a memory system controller 140, a memory device 145, a local controller) may include one or more instances of a circuit 200 to delay clock signaling (e.g., generated at an oscillator of the memory system 110, clock signaling received over one or more channels 115 from a host system 105), which may be used for initiating various operations of the memory system 110 (e.g., access operations, data transfer operations, communication operations, multiplexing operations). Additionally, or alternatively, a host system 105 (e.g., a processor 125, a host system controller 120) or a memory system 110 (e.g., a memory system controller 140, a memory device 145, a local controller 150) may include one or more instances of a circuit 200 to adjust signal timing (e.g., of clock signals, of data signals, of control signals, of command signals) relative to a latching event, such as a latching to initiate a data processing operation (e.g., to perform a processing operation), a latching to initiate a data communication operation (e.g., to latch a received signal), a latching to initiate an access operation (e.g., to access a memory array 155), or others. For example, a host system 105, a memory system, or both may implement a delay circuit 200 for training of channels 115 (e.g., for data channel and data channel strobe training, such as DQ-DQS training, for decision feedback equalization (DFE) tap training, for phase timing training). Although these represent some examples for implementing a delay circuit 200 at one or more components of a system, the described techniques may be implemented in other applications for delaying an output signal relative to an input signal.

A circuit 200 may be configured to receive a signal at a respective input 240. For example, a circuit 200 (e.g., an input 240) may include or be coupled with a terminal of the electronic device that is configured to output (e.g., generate, provide) the first signal. The first signal may be a timing signal (e.g., a clock signal), a data signal (e.g., a data transfer signal, random data movement signaling), a command signal, a communication signal, a control signal, or some other signal. In some examples, the first signal may be received from an external system (e.g., from an external oscillator, from an external source), such as a signal source included in a different device than a device that includes an instance of a circuit 200. In some other examples, the first signal may be generated by a signal source integrated with a circuit 200 (e.g., via an on-board oscillator, via an on-board signal source, not shown). In some examples, a circuit 200 may be implemented in or as part of a memory device and may include (e.g., be coupled with) one or more memory arrays, a signal source (e.g., a timing signal source, an oscillator) associated with the first signal, or both.

In some cases, systems (e.g., a system 100, a memory systems 110, a host system 105, or other electronic systems) may implement circuitry associated with delaying an input signal at an output of the circuitry. However, at least some of the circuit elements (e.g., capacitive circuit elements) used to generate a delayed output signal may be associated with reduced bandwidth capabilities (e.g., due to reducing a slew rate of the input signal, due to reduced edge-rates) or may be susceptible to signal fluctuations (e.g., jitter). Such effects may degrade signal integrity and may constrain bandwidth of the system (e.g., processing speed, memory access speed, throughput). Additionally, some systems (e.g., some delay circuits) may not support configurable control of a delay along a signal path. For instance, a delay (e.g., a time value of the delay) may be preconfigured based on physical characteristics (e.g., physical components) of a system, and the system may not support dynamically adapting delay circuitry to support various applications, manufacturing characteristics, or operating characteristics (e.g., operating speed, operating frequency, operating temperature, operating voltage), among other limitations.

In accordance with one or more techniques described herein, a circuit 200 may be configured to support delay control of an output signal, relative to an input signal, while maintaining relatively high bandwidth capabilities (e.g., processing bandwidth, communication bandwidth, memory access bandwidth, timing signal frequency) and signal integrity (e.g., by avoiding addition of capacitance for delay control, for steeper transitions between states). For example, a circuit 200 may include one or more feedback paths (e.g., feedback paths with interleaved coupling points along the forward signal path), and elements of the circuit 200 may control a delay based on a strength of one or more feedback signals (e.g., inverted feedback signals) that are introduced into the forward path.

A circuit 200 may include a plurality of delay elements coupled in series (e.g., along a forward path, along a central path) between an input 240 and an output 245. In the illustrated example, such delay elements are implemented as a chain of inverters 205 (e.g., inverters 205-a-1 through 205-a-10, an inverter chain) that are sequentially coupled between the input 240 and the output 245. For example, an output of an inverter 205-a-1 may be coupled with an input of an inverter 205-a-2, and the output of the inverter 205-a-2 may be coupled with an input of an inverter 205-a-3 and so on (e.g., along the forward path). Such delay elements may be coupled along a sequence of alternating odd nodes 210 and even nodes 210 between the input 240 and the output 245. For example, a delay element illustrated by inverter 205-a-2 may precede a node 210-a-1 (e.g., an odd node) along the forward path, a delay element illustrated by inverter 205-a-3 may be between the node 210-a-1 and a node 210-a-2 (e.g., an even node following an odd node) along the forward path, and so on, among other implementations of alternating odd and even nodes 210. Although some delay elements in accordance with the described techniques may be associated with a signal inversion (e.g., by way of inverters 205-a), some other delay elements coupled between an input 240 and an output 245 in accordance with the described techniques may not be associated with a signal inversion, or may implement other arrangements of circuitry (e.g., logic circuitry, logic gates, NAND gates, transistor types and arrangements).

A circuit 200 may also include one or more feedback paths that are coupled with the forward path at one or more nodes 210-a along the forward path (e.g., interleaved feedback paths). For example, a feedback path may include a feedback element configured to send a signal (e.g., an inverted signal, an opposing signal, a suppressing signal) from one node 210 to a preceding node 210 along the forward path. In the illustrated example, such feedback elements include inverters 205-b along one or more feedback paths (e.g., feedback loops) of the circuit 200 (e.g., between one or more pairs of even nodes 210, between one or more pairs of odd nodes 210). For example, a circuit 200 may include one or more feedback elements (e.g., as an inverter 205-b) that are configured to send an inverted signal of a corresponding one of the even nodes 210-a to a corresponding preceding one of the even nodes 210-a (e.g., inverter 205-b-5 sending an inverted signal of even node 210-a-4 to preceding even node 210-a-2, which may be an immediately preceding even node, and so on). Additionally, or alternatively, a circuit 200 may include one or more feedback elements (e.g., as an inverter 205-b) that are configured to send an inverted signal of a corresponding one of the odd nodes 210-a to a corresponding preceding one of the odd nodes 210-a (e.g., transistor 205-b-1 sending an inverted signal of odd node 210-a-3 to preceding odd node 210-a-1, which may be an immediately preceding odd node, and so on). Accordingly, inverters 205-b may each have a respective input (e.g., a respective input 235-a-2) that is coupled with an output of a first inverter 205-a of the chain of inverters 205-a, and a respective output (e.g., a respective output 260) that is coupled with an input of a second inverter 205-a of the chain of inverters 205-a that precedes (e.g., immediately precedes) the first inverter 205-a along the chain of inverters 205.

Although inverting feedback elements are illustrated and described with reference to pairs of even nodes and pairs of alternating odd nodes (e.g., across a pair of inverting delay elements as inverters 205-a, across an even quantity of delay elements as inverters 205-a), inverting feedback elements may be implemented as feedback to any quantity of one or more delay elements (e.g., from a node 210 to any preceding node 210) when such delay elements are not associated with a signal inversion. Further, although some feedback elements in accordance with the described techniques may be associated with a signal inversion (e.g., by way of inverters 205-a), some other feedback components implemented along a forward path in accordance with the described techniques may not be associated with a signal inversion (e.g., when implemented across an odd quantity of inverters 205-a), or may implement other arrangements of circuitry (e.g., logic circuitry, logic gates, NAND gates, transistor types and arrangements).

Although the illustrated example of a circuit 200 includes certain quantities of inverters 205 (e.g., certain quantities of delay elements, certain quantities and configurations of feedback elements), various instances of a circuit 200 may include different quantities and configurations of components, including inverters and other components, in accordance with the described techniques to implement different relative delays, which may be implemented in a given electronic device to support generating output signals with different relative timings. For example, although FIG. 2 illustrates a circuit 200 with a non-limiting example of a ten-stage forward path (e.g., with ten inverters 205-a), a circuit 200 may include any quantity of inverters (e.g., any quantity of stages) including more or fewer inverters 205-a along the forward path, among other implementations of delay elements, which may support different amounts of delay at an output 245 relative to an input 240. Further, although FIG. 2 illustrates a non-limiting example of quantities of feedback paths and inverters 205-b, a circuit 200 may include any quantity of feedback paths with any quantity of feedback inverters 205-b in each feedback path, among other implementations of feedback elements. In some examples, a delay control may be proportional to the quantity of feedback paths and quantity of inverters 205-b.

In some examples, at least some, if not each inverter 205-a (e.g., along the forward path) may include a circuit 215 (e.g., as illustrated as an expansion of the inverter 205-a-1, as an example of an inverting delay element), which may include two transistors (a p-type transistor and an n-type transistor, a p-over-n inverter) that are coupled as shown. For example, an inverter 205-a may include an input 250 and an output 255. At the output 255, the circuit 215 may output (e.g., generate) an inverted version of a signal provided at the input 250 (e.g., as a voltage inversion). In some examples, an inverter 205-a may generate an inverted signal based on a voltage source 225 (e.g., Vdd, a high logic state voltage) and a voltage source 230 (e.g., a ground voltage, a low logic state voltage). For example, if a relatively low voltage signal is provided at the input 250, the circuit 215 (e.g., the p-type transistor) may couple the voltage source 225 with the output 255 to generate a relatively high voltage signal at the output. If a relatively high voltage signal is provided at the input 250, the circuit 215 (e.g., the n-type transistor) may couple the voltage source 230 with the output 255 to generate a relatively low voltage signal at the output 255.

In some examples, at least some, if not each inverter 205-b (e.g., along respective feedback paths) may include a circuit 220 (e.g., as illustrated as an expansion of the inverter 205-b-1, as an example of implementing an inverting feedback element), which may include four transistors (e.g., two p-type transistors and two n-type transistors, as a tri-state-able inverter). A circuit 220 of an inverter 205-b may include multiple (e.g., three) inputs 235 and an output 260. At the output 260, the circuit 220 may output (e.g., generate) an inverted version of a signal provided at an input 235-a-2 (e.g., as a voltage inversion). In some examples, an inverter 205-b may generate an inverted signal based on a voltage source 225 and a voltage source 230 (e.g., which may be the same voltage sources or different voltages sources as inverters 205-a). For example, an inverter 205-b may adjust a strength of an inverted signal at an output 260 based on respective voltages applied to an input 235-a-1 (e.g., a header gate bias input) and an input 235-a-3 (e.g., a footer gate bias input). Respective inputs 235-a-1 of inverters 205-b may be coupled with respective voltage sources 265 (e.g., respective header voltage sources, VH₁, VH₂, VH₃, VH₄, and so on), and respective inputs 235-a-3 of inverters 205-b may be coupled with respective voltage sources 270 (e.g., respective footer voltage sources, VF₁, VF₂, VF₃, VF₄, and so on). Although the circuit 220 is illustrated as an example for implementing an inverter 205-b, in some examples, the circuit 220 may be implemented for an inverter 205-a (e.g., along a forward path), which may support shutting down the forward path, reducing leakage currents, and other functionality.

In some examples, each inverter 205-b may correspond to (e.g., be coupled between) an even quantity of inverters 205-a (e.g., two) along the forward path. However, in some examples, an output of a last inverter 205-a along the chain of inverters 205-a may be coupled with its own input via an even quantity of inverters 205-b (e.g., to maintain an overall odd quantity of feedback inverters relative to an even quantity of the forward path inverters). As an example, an output of the inverter 205-a-10 (e.g., at node 210-a-9) may be coupled with its own input at node 210-a-8 via a pair of inverters 205-b (e.g., inverters 205-b-8 and 205-b-9). In some examples, multiple feedback elements (e.g., multiple inverters 205-b) may be coupled along a feedback path (e.g., feedback loop). For example, an output of at least one of inverters 205-b may be directly coupled with an input of another of the inverters 205-b. As an example, the output of the inverter 205-b-2 may be directly coupled with the input of the inverter 205-b-1, and so on.

Each inverter 205-b may include a first input coupled with a respective voltage source 265, a second input coupled with a respective voltage source 270, and a third input coupled with an output of a respective inverter 205-a. In some examples, a delay (e.g., a duration of the delay) of the output signal of the delay circuit 200 (e.g., at the output 245) relative to the input signal may be based on respective first voltages of the voltage sources 265 and respective second voltages of the voltage sources 270. In some examples, one or more of the voltage sources 265 (e.g., each header gate bias) may commonly generate (e.g., provide) a same voltage level for each of the inverters 205-b, or one or more of the voltage sources 265 may each independently generate respective voltage levels (e.g., different voltage levels). Similarly, one or more of the respective voltage sources 270 (e.g., each footer gate bias) may commonly generate a same voltage level for each of the inverters 205-b, or one or more of the voltage sources 270 may each independently generate respective voltage levels (e.g., different voltage levels).

In some implementations, respective voltage sources 265 and voltage sources 270 may be associated with controlling a strength of an inverted signal at a given output 260 (e.g., to a given input 250, to a given output 255, to a respective node 210), among other signal characteristics. For instance, a circuit 200 (e.g., or other circuitry controlling the electronic device) may increase or decrease a voltage level of a voltage source 265 (e.g., a header gate bias voltage) or a voltage source 270 (e.g., a footer gate bias voltage). Accordingly, the circuit 200 may adjust a bias of at least a first transistor (e.g., a p-type transistor) that is coupled between the output 260 and the voltage source 225, or at least a second transistor (e.g., an n-type transistor) that is coupled between the output 260 and the voltage source 230, or both. Such bias voltages may at least partially enable or disable the first transistor and/or the second transistor (e.g., at least partially activate a respective channel portion of the transistor), thus allowing variable (e.g., configurable, controllable) levels of charge (e.g., voltage) to be provided to the output 260 via the voltage source 225 or drained from the output 260 via the voltage source 230.

At one or more of the nodes 210-a, a feedback signal from a feedback element (e.g., an inverter 205-b) may contend with the forward signal along the main forward path. Such signal contention may reduce (e.g., compress, oppose, suppress) a voltage magnitude associated with the forward signal. Based on the reduced voltage level, the forward signal may transition from one voltage state (e.g., a high voltage state, a low voltage state) to a second voltage state (e.g., a low voltage state, a high voltage state) more quickly (e.g., based on a reduced voltage range traversed by the signal, which may be related to a given slew rate). A reduced transition duration may advance (e.g., pull ahead) the signal in a time domain, which may appear at the output 245 as an overall delay reduction. Further, a delay in the forward signal may accumulate at each node 210-a along the forward path (e.g., based on the accumulation of feedback signals along the forward path).

Various options for delay control are possible in a circuit 200 based on possible implementations of feedback elements (e.g., as inverters 205-b, or other implementations). For example, header and footer voltages of inverters 205-b may be controlled via feedback width control (e.g., via finger enabling and/or disabling), enabling and/or disabling a subset of feedback loops (e.g., enabling every other feedback loop, enabling each feedback loop in a first feedback path), or based on variable header and footer length (e.g., via source and drain tapping), among other implementations. Further, because a delay of a delay circuit 200 may be based on the strength of the feedback signal (e.g., as a strength of suppression) from the feedback elements, the delay may be controlled (e.g., modified) by adjusting analog voltages on the header and footer gates of inverters 205-b (e.g., by voltage sources 265 and 270), which may be performed asymmetrically across different inverters 205-b, among other feedback element implementations. For example, applying various analog voltages to the header and footer gates of the inverters 205-b, the delay circuit 200 may support adjusting rising slew rates, falling slew rates, or a transition point (e.g., a crossing point, a time of crossing a midpoint between voltage states) of signals along the delay circuit 200, or any combination thereof, which may support a symmetric adjustment (e.g., using symmetric shifts in header and footer voltages) or asymmetric adjustment (e.g., using asymmetric shifts in header and footer voltages) of rising and falling slew rates, among other examples. Additionally, or alternatively, a delay of a delay circuit 200 may be modified via digital control of the header and footer gates of the inverters 205-b. For example, the digital control may include incrementally enabling and/or disabling additive legs of header and footer gates (e.g., by increasing a quantity of header and footer transistors), or multiple legs of an inverter 205-b. Further, header and/or footer transistors may be shared across one or more inverters 205-b (e.g., with a p-type transistor coupled with an input 235-a-1 being shared among multiple inverters 205-b, with an n-type transistor coupled with an input 235-a-3 being shared multiple inverters 205-b).

In some examples, it may be advantageous to utilize voltages provided by supplies other than the supply of the delay chain for controlling the delay. For example, the adjusting the header or footer voltages for controlling the delay may benefit from an analog voltage applied to the gate that is higher than the nominal circuit voltage. In some examples, VPP (e.g., >1.5V) may be applied to enable/disable the strength of the feedback, while other circuits (e.g., forward path and feedback circuits) may be powered by VDD (e.g., ˜1.0V).

The inverters 205-a are shown as including a circuit 215 and inverters 205-b are shown as including a circuit 220 as non-limiting examples. However, the inverters 205-a and the inverters 205-b, among other delay elements and feedback elements, may include different circuitry than the circuits shown (e.g., other transistor circuitry, or other circuitry that implements an electrical inversion operation). For example, inverters 205-a, inverters 205-b, or both may be implemented with one or more logic elements (e.g., NAND gates), which may support other logic functions, improved control of a delay, improved power savings, or other logical operating expectations. In some examples, inverters 205-a may be alternatively implemented with circuits 220 (e.g., as tri-statable inverters). For example, inverters 205-a may also be associated with header voltage sources and footer voltage sources, which may allow for disabling the forward path and for reducing leakage currents. In some examples, inverters 205-a, inverters 205-b, or both may have different sizes (e.g., channel widths, at different locations along a forward path between an input 240 and an output 245) and may have inputs and outputs associated with different physical lengths (e.g., different signal path lengths). For example, a size of each inverter 205-a along the forward path may increase relative to a previous inverter 205-a. Additionally, or alternatively, the lengths (e.g., trace lengths, conductive line lengths) may be increased after each inverter 205-a. Such variations in inverter size and path length may improve signal integrity at the output 245.

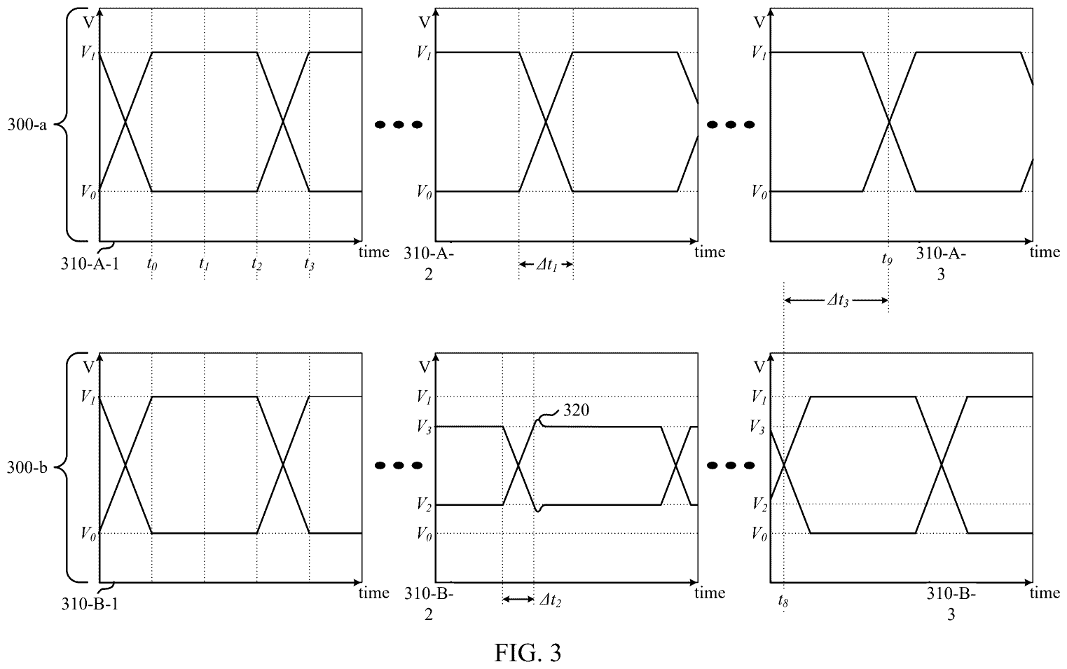

FIG. 3 shows an example of a timing diagram 300-a and a timing diagram 300-b that support signal delay control with inverted feedback in accordance with examples as disclosed herein. The timing diagrams 300 illustrate examples of a circuit 200 operating in accordance with different configurations, including different signals of different nodes of the different configurations. For example, the diagram 310-a-1 and the diagram 310-b-1 may show a signal at a first node (e.g., an input 240) of the circuit 200 during a time window (e.g., times t₀ through t₃), the diagram 310-a-3 and the diagram 310-b-3 may show a signal at a third node (e.g., an output 245, a node 210-a-9) of the circuit 200, and the diagram 310-a-2 and the diagram 310-b-2 may show a signal at a second node (e.g., an inner node, one of nodes 210-a-1 through 210-a-8) between the first node and the third node of the circuit 200. The timing diagram 300-a may be associated with a first configuration of the circuit 200 in which one or more feedback elements (e.g., inverters 205-b) are disabled (e.g., without feedback signals introduced into the forward signal path). The timing diagram 300-b may be associated with a second configuration in which one or more feedback elements are at least partially enabled (e.g., providing contending feedback signals into the forward signal path).

A circuit 200 may receive a first signal (e.g., a timing signal, a data signal, a control signal, a command signal) at an input 240 (e.g., of a chain of delay elements, of a chain of inverters 205-a). The input signal may be shown in the diagram 310-a-1 and the diagram 310-b-1. A delay may be accumulated through each stage (e.g., through successive delay elements, at successive nodes 210-a) of the circuit 200 along the forward path. For instance, the diagram 310-a-2 and the diagram 310-b-2 may show the forward signal at an intermediate node (e.g., node 210-a-5) of the circuit 200 between the input 240 and the output 245. That is, the signal may have been processed through one or more delay elements (e.g., other nodes, such as nodes 210-a-3 and node 210-a-4) prior to the signals of diagrams 310-a-2 and 310-b-2, and may be further be processed by one or more additional delay elements (e.g., other nodes, such as nodes 210-a-6 and 210-a-7) after the signals of diagrams 310-a-2 and 310-b-2. The circuit 200 may generate a second signal at an output 245 based on receiving the first signal, and the second signal may have a delay relative to the first signal. The diagram 310-a-3 and the diagram 310-b-3 may show the delayed signal at the output 245.

Generating the second signal may be based on at least one first delay element (e.g., a first inverter 205-a, such as inverter 205-a-7) having an output that is coupled with an input of a respective preceding second delay element (e.g., a second inverter 205-a, such as inverter 205-a-6, at node 210-a-5) via a feedback element (e.g., a feedback inverter, such as inverter 205-b-3, a feedback element that is not along the forward path) that is configured to send a suppressing signal to the input of the preceding delay element (e.g., sending an inverted signal of the node 210-a-7 to the node 210-a-5). In some examples, generating the second signal may be based on an output of the preceding second delay element being directly coupled with an input of the at least one first delay element (e.g., as a pair of inverters 205-a associated with a respective feedback inverter 205-b, such as paired inverters 205-a-6 and 205-a-7). In some examples, generating the second signal may be based on an output of a respective feedback element (e.g., an inverter 205-b, such as inverter 205-b-3) being directly coupled with an input of another feedback element (e.g., another inverter 205-b, such as inverter 205-b-2).

The delay of the signal at an output 245 relative to an input 240 may be based on an output of a feedback element (e.g., an inverter 205-b, such as inverter 205-b-3) reducing a voltage level provided to an input of a delay element (e.g., an inverter 205-a, such as inverter 205-a-6) along the forward path. For example, as illustrated in diagram 310-b-2, the voltage range associated with at least a portion of the input signal be reduced (e.g., compressed, relative to the signal of diagram 310-a-2) from an initial range of V₀ to V₁ to a compressed range from V₂ to V₃. In some examples, the signal may include an overshoot 320, which may be associated with the contending feedback signal (e.g., from the signal at the node 210-a-7 being delayed relative to the signal at the node 210-a-5 from one or more of the inverters 205-a-7, 205-a-8, and 205-b-3). However, in some other examples, an overshoot 320 may not be present, which may be related to a degree of capacitance at the node 205-a-5, an amount of delay along the forward path or along a feedback path, among other electrical characteristics.

A voltage reduction (e.g., related to an inverted feedback signal suppression, after overshoot 320, where applicable) may cause the rising edges and falling edges of the signal to transition from one voltage state to another at a given node 210-a or inverter 205-a in a relatively shorter duration (e.g., for a given slew rate, which may be the same or similar for different configurations of a circuit 200). For example, for the signal illustrated by diagram 310-a-2, for which suppressing feedback signals may be disabled, a transition between signal states may involve a duration Δt1, whereas for the signal illustrated by diagram 310-b-2, for which suppressing signals are enabled (e.g., through inverter 205-b-3), a transition between signal states may involve a duration Δt2 that is shorter than the duration Δt1, associated with a shorter delay (e.g., at an output of inverter 205-a-6, at an input of inverter 205-a-7). Accordingly, an amount of time involved in a given signal transition can be configured based on an amount of suppressing feedback provided along the forward path. Such delays (e.g., a shortened delays, compressed delays) may accumulate at each stage (e.g., through multiple nodes 210-a) of the circuit 200, which may reduce an overall delay at the output 245 relative to the input 240. For example, the diagrams 310-a-3 and 310-b-3 may show a difference between the crossing point of the signal at time t₈ in diagram 310-b-3 (e.g., in the case that one or more of the feedback inverters 205-b are at least partially activated), and the crossing point of the signal at time to in the diagram 310-a-3 (e.g., in the case that the feedback inverters 205-b are deactivated). Accordingly, activating one or more feedback elements in accordance with the timing diagram 300-b may be associated with an overall delay that is shorter by a duration Δt3.

A circuit 200 may be configured to control a delay of an input signal by adjusting one or more voltage values of the respective voltage sources 265 and the respective voltage sources 270. For example, an inverter 205-b may be respective tri-state inverter, and a first voltage may be applied (e.g., by the voltage source 265) at a first input (e.g., an input 235-a-1) of the respective tri-state inverter. Further, a second voltage may be applied (e.g., by the voltage source 270) at a second input (e.g., an input 235-a-3) of the inverter 205-b. Accordingly, the delayed second signal may be generated based on applying the first voltage and applying the second voltage, while a third input (e.g., an input 235-a-2) of the respective tri-state inverter may be coupled with the output of an inverter 205-a along the forward path.

In some examples, generating the second signal may include controlling a value of the delay relative to the first signal on a first value of the respective voltage sources 265 and a second value of the respective voltage sources 270. In some examples, the voltage source 265 (e.g., the header voltage source) and the voltage source 270 (e.g., the footer voltage source) may be provided with complimentary gate bias values (e.g., a sum of the values of the voltage source 265 and the voltage source 270 may be equal to a threshold voltage, such as one volt). In some examples, the voltage sources 265 and the voltage sources 270 may be adjusted at relatively small increments (e.g., in an analog manner), which may support a fine tuning of the delay value at the output 245. That is, by adjusting the analog voltages of the header and footer inputs (e.g., inputs 235-a-1 and inputs 235-a-3 respectively) at the inverters 205-b, the electronic device may increase or decrease the delay (e.g., a time difference between t₈ and t₉) according to the analog voltage values to achieve a target delay (e.g., a target rising slew rate of a signal, a target falling slew rate of a signal, a target transition crossing point of a signal, or a combination thereof) at the output 245. In additional, or alternative examples, the electronic device may digitally control the header and footer inputs of the inverters 205-b. For instance, the electronic device may enable or disable a subset of inverters 205-b in the circuit 200 to achieve a target delay value (e.g., a target rising slew rate of a signal, a target falling slew rate of a signal, a target transition crossing point of a signal, or a combination thereof). Further, in any case, the electronic device may uniformly control all of the voltage sources 265 (e.g., with a same first voltage value) and the voltage sources 270 (e.g., with a same second voltage value) of the inverters 205-b, or may independently control each of the voltage sources 265 and the voltage sources 270 of the inverters 205-b (e.g., with different respective voltage values).

In some examples, the circuits and timing diagrams described herein may be implemented in the context of calibrating and minimizing sew between different phases of a clock. For example, the circuits and timing diagrams may be implemented in two-phase clocking where complementary clock signals are transmitted or otherwise sent together, but only the rising (or falling) portion of each of the two complements is employed. Depending on routing context on the IC and/or gate delays, there may be some systemic misalignment in the timing of the complimentary signals, which may otherwise lead to lost timing margin. The present invention allows for one or both of the complimentary clock signals to be adjusted in time relative to the compliment, thus maximizing margin. Such adjustments may be made during a probe test or another testing phase of manufacturing (e.g., of an associated device) or in-situ with a closed-loop control of the delays.

In other examples, the circuits and timing diagrams described herein may be implemented in the context of optimizing the timing of a clock at a data sampler or a flip-flop. Such timing adjustments may maximize the timing margin of the clock signals.

Accordingly, electronic devices may include one or more instances of a circuit 200 to support an increased range of delay adjustments (e.g., fine delay-tuning with a relatively large range), which may enable more efficient operations in electronic systems that utilize delay circuits (e.g., memory systems 110, host systems 105, memory devices 145). Additionally, the techniques described herein may improve a speed of a final edge (e.g., at a nearly constant slew-rate) instead of reducing the final edges speed (e.g., instead of adding capacitance to slow-down edges), and may reduce accumulation of signal fluctuations (e.g., reduced jitter accumulation). Further, the one or more feedback path may also counteract signal attenuation (e.g., associated with high frequency signals), which may simultaneously control inter-signal interference and enable relatively high processing bandwidth (e.g., high-speed data movement).

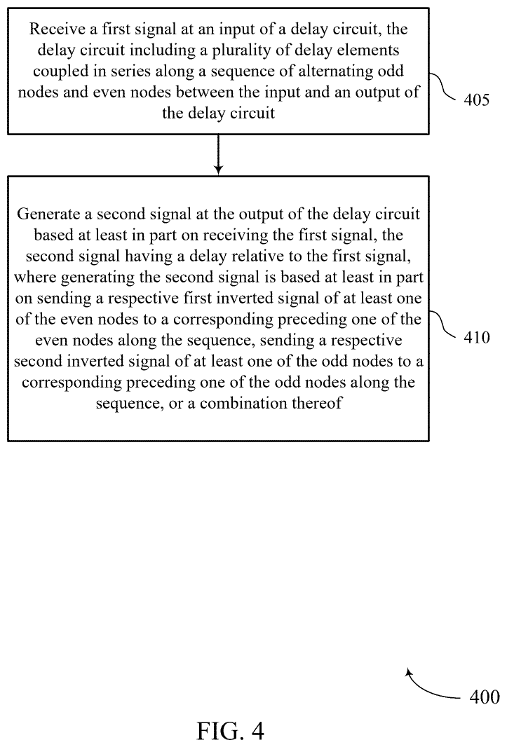

FIG. 4 shows a flowchart illustrating a method 400 that supports signal delay control with inverted feedback in accordance with examples as disclosed herein. The operations of method 400 may be implemented by an electronic device or its components as described herein. For example, the operations of method 400 may be performed by an electronic device as described with reference to FIGS. 1 through 3. In some examples, an electronic device may execute a set of instructions to control the functional elements of the device to perform the described functions. Additionally, or alternatively, the electronic device may perform aspects of the described functions using special-purpose hardware.

At 405, the method may include receiving a first signal at an input (e.g., an input 240) of a delay circuit (e.g., a delay circuit 200), the delay circuit including a plurality of delay elements (e.g., inverters 205-a or other delay elements) coupled in series along a sequence of alternating odd nodes and even nodes (e.g., nodes 210) between the input and an output of the delay circuit.

At 410, the method may include generating a second signal at the output of the delay circuit based at least in part on receiving the first signal, the second signal having a delay relative to the first signal, where generating the second signal is based at least in part on sending a respective first inverted signal (e.g., via a feedback element, via an inverter 205-b) of at least one of the even nodes to a corresponding preceding one of the even nodes along the sequence, sending a respective second inverted signal of at least one of the odd nodes to a corresponding preceding one of the odd nodes along the sequence, or a combination thereof.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a first signal at an input (e.g., an input 240) of a delay circuit (e.g., a delay circuit 200), the delay circuit including a plurality of delay elements (e.g., inverters 205-a or other delay elements) coupled in series along a sequence of alternating odd nodes and even nodes (e.g., nodes 210) between the input and an output of the delay circuit, and generating a second signal at the output of the delay circuit based at least in part on receiving the first signal, the second signal having a delay relative to the first signal, where generating the second signal is based at least in part on sending a respective first inverted signal (e.g., via a feedback element, via an inverter 205-b) of at least one of the even nodes to a corresponding preceding one of the even nodes along the sequence, sending a respective second inverted signal of at least one of the odd nodes to a corresponding preceding one of the odd nodes along the sequence, or a combination thereof.

Aspect 2: The method, apparatus, or non-transitory computer-readable medium of aspect 1, where generating the second signal is based at least in part on the corresponding preceding one of the even nodes being an immediately preceding even node to the corresponding one of the even nodes, or the corresponding preceding one of the odd nodes being an immediately preceding odd node to the corresponding one of the even nodes, or both.

Aspect 3: The method, apparatus, or non-transitory computer-readable medium of any of aspects 1 through 2, where the delay of the second signal relative to the first signal is based at least in part on the inverted signal corresponding to the one of the even nodes reducing a voltage at the corresponding previous one of the even nodes, or the inverted signal corresponding to the one of the odd nodes reducing a voltage at the corresponding previous one of the odd nodes, or a combination thereof.

Aspect 4: The method, apparatus, or non-transitory computer-readable medium of any of aspects 1 through 3, further including operations, features, circuitry, logic, means, or instructions, or any combination thereof for generating the respective first inverted signal, generating the respective second inverted signal, or both via a respective tri-statable inverter (e.g., in accordance with a circuit 220).

Aspect 5: The method, apparatus, or non-transitory computer-readable medium of aspect 4, where generating the respective first inverted signal, generating the respective second inverted signal, or both is based at least in part on applying a first voltage at a first input (e.g., an input 235-a-1) of the respective tri-state inverter and applying a second voltage at a second input (e.g., an input 235-a-3) of the respective tri-state inverter.

Aspect 6: The method, apparatus, or non-transitory computer-readable medium of aspect 5, further including operations, features, circuitry, logic, means, or instructions, or any combination thereof for controlling a value of the delay relative to the first signal based at least in part on controlling a first value of the first voltage and controlling a second value of the second voltage.

Aspect 7: The method, apparatus, or non-transitory computer-readable medium of any of aspects 1 through 6, where generating the second signal is based at least in part on an output of a last delay element along the sequence being coupled with an input of the last delay element via an even quantity of inverters (e.g., a pair of inverters 205-b, inverters 205-b-8 and 205-b-9).

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 8: An electronic device, including: an input terminal (e.g., an input 240); an output terminal (e.g., an output 245); and a delay circuit (e.g., a delay circuit 200) including: a plurality of delay elements (e.g., inverters 205-a) coupled in series along a sequence of alternating odd nodes and even nodes (e.g., nodes 210) between the input terminal and the output terminal; one or more first feedback elements (e.g., inverters 205-b) each configured to send an inverted first signal of a corresponding one of the even nodes to a corresponding preceding one of the even nodes along the sequence; and one or more second feedback elements (e.g., inverters 205-b) each configured to send an inverted second signal of a corresponding one of odd nodes to a corresponding preceding one of the odd nodes along the sequence.

Aspect 9: The electronic device of aspect 8, where, for at least one of the one or more first feedback elements, the corresponding preceding one of the even nodes is an immediately preceding even node to the corresponding one of the even nodes, or, for at least one of the one or more second feedback elements, the corresponding preceding one of the odd nodes is an immediately preceding odd node to the corresponding one of the even nodes, or both.

Aspect 10: The electronic device of any of aspects 8 through 9, where an output of at least one of the one or more first feedback elements is directly coupled with an input of another of the one or more first feedback elements, or an output of at least one of the one or more second feedback elements is directly coupled with an input of another of the one or more second feedback elements, or both.

Aspect 11: The electronic device of any of aspects 8 through 10, where a delay of the delay circuit between the output terminal and the input terminal is based at least in part on the inverted first signal corresponding to the one of the even nodes reducing a voltage at the corresponding previous one of the even nodes, or the inverted second signal corresponding to the one of the odd nodes reducing a voltage at the corresponding previous one of the odd nodes, or a combination thereof.

Aspect 12: The electronic device of any of aspects 8 through 11, where at least one of the one or more first feedback elements, or at least one of the one or more second feedback elements, or both includes: a first input (e.g., an input 235-a-1) coupled with a first voltage source (e.g., a voltage source 265); and a second input (e.g., an input 235-a-3) coupled with a second voltage source (e.g., a voltage source 270), where a delay of the delay circuit between the output terminal and the input terminal is based at least in part on a first voltage of the first voltage source and a second voltage of the second voltage source.

Aspect 13: The electronic device of any of aspects 8 through 12, where an output of a last delay element along the sequence is coupled with an input of the last delay element via an even quantity of inverters.

Aspect 14: The electronic device of any of aspects 8 through 13, where at least one of the plurality of delay elements includes a p-over-n inverter (e.g., in accordance with a circuit 215).

Aspect 15: The electronic device of any of aspects 8 through 14, where at least one of the plurality of delay elements includes a tri-statable inverter (e.g., in accordance with a circuit 220).

Aspect 16: The electronic device of any of aspects 8 through 15, where at least one of the one or more first feedback elements, at least one of the one or more second feedback elements, or both includes a tri-statable inverter (e.g., in accordance with a circuit 220).

Aspect 17: The electronic device of any of aspects 8 through 16, where at least one of the one or more first feedback elements, at least one of the one or more second feedback elements, or both includes a NAND gate.

An apparatus is described. The following provides an overview of aspects of the apparatus as described herein:

Aspect 18: A memory device (e.g., a memory device 145), including: one or more memory arrays (e.g., memory array(s) 155); a signal source associated with a first signal; and a delay circuit (e.g., a delay circuit 200) configured to generate a second signal, having a delay relative to the first signal, associated with accessing the one or more memory arrays based at least in part on receiving the first signal from the signal source, the delay circuit including: a plurality of delay elements (e.g., inverters 205-a) coupled in series along a sequence of alternating odd nodes and even nodes (e.g., nodes 210) between an input of the delay circuit and an output of the delay circuit; one or more first feedback elements (e.g., inverter(s) 205-b) each configured to send an inverted first signal of a corresponding one of the even nodes to a corresponding preceding one of the even nodes along the sequence; and one or more second feedback elements (e.g., inverter(s) 205-b) each configured to send an inverted second signal of a corresponding one of odd nodes to a corresponding preceding one of the odd nodes along the sequence.

Aspect 19: The memory device of aspect 18, where the delay is based at least in part on the inverted first signal corresponding to the one of the even nodes reducing a voltage at the corresponding previous one of the even nodes, or the inverted second signal corresponding to the one of the odd nodes reducing a voltage at the corresponding previous one of the odd nodes, or a combination thereof.

Aspect 20: The memory device of any of aspects 18 through 19, where: at least one of the plurality of delay elements includes a p-over-n inverter (e.g., in accordance with a circuit 215); and at least one of the one or more first feedback elements, at least one of the one or more second feedback elements, or both includes a tri-statable inverter (e.g., in accordance with a circuit 220).

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An electronic device, comprising:
an input terminal;
an output terminal; and
a delay circuit comprising:
a plurality of delay elements coupled in series along a sequence of alternating odd nodes and even nodes between the input terminal and the output terminal;
one or more first feedback elements each configured to send an inverted first signal of a corresponding one of the even nodes to a corresponding preceding one of the even nodes along the sequence; and
one or more second feedback elements each configured to send an inverted second signal of a corresponding one of odd nodes to a corresponding preceding one of the odd nodes along the sequence.

2. The electronic device of claim 1, wherein, for at least one of the one or more first feedback elements, the corresponding preceding one of the even nodes is an immediately preceding even node to the corresponding one of the even nodes, or for at least one of the one or more second feedback elements, the corresponding preceding one of the odd nodes is an immediately preceding odd node to the corresponding one of the even nodes, or both.

3. The electronic device of claim 1, wherein an output of at least one of the one or more first feedback elements is directly coupled with an input of another of the one or more first feedback elements, or an output of at least one of the one or more second feedback elements is directly coupled with an input of another of the one or more second feedback elements, or both.

4. The electronic device of claim 1, wherein a delay of the delay circuit between the output terminal and the input terminal is based at least in part on the inverted first signal corresponding to the one of the even nodes reducing a voltage at the corresponding previous one of the even nodes, or the inverted second signal corresponding to the one of the odd nodes reducing a voltage at the corresponding previous one of the odd nodes, or a combination thereof.

5. The electronic device of claim 1, wherein at least one of the one or more first feedback elements, or at least one of the one or more second feedback elements, or both comprises:
a first input coupled with a first voltage source; and
a second input coupled with a second voltage source,
wherein a delay of the delay circuit between the output terminal and the input terminal is based at least in part on a first voltage of the first voltage source and a second voltage of the second voltage source.

6. The electronic device of claim 1, wherein an output of a last delay element along the sequence is coupled with an input of the last delay element via an even quantity of inverters.

7. The electronic device of claim 1, wherein at least one of the plurality of delay elements comprises a p-over-n inverter.

8. The electronic device of claim 1, wherein at least one of the plurality of delay elements comprises a tri-statable inverter.

9. The electronic device of claim 1, wherein at least one of the one or more first feedback elements, at least one of the one or more second feedback elements, or both comprises a tri-statable inverter.

10. The electronic device of claim 1, wherein at least one of the one or more first feedback elements, at least one of the one or more second feedback elements, or both comprises a NAND gate.

11. A method at an electronic device, comprising:
receiving a first signal at an input of a delay circuit, the delay circuit including a plurality of delay elements coupled in series along a sequence of alternating odd nodes and even nodes between the input and an output of the delay circuit; and
generating a second signal at the output of the delay circuit based at least in part on receiving the first signal, the second signal having a delay relative to the first signal, wherein generating the second signal is based at least in part on sending a respective first inverted signal of at least one of the even nodes to a corresponding preceding one of the even nodes along the sequence, sending a respective second inverted signal of at least one of the odd nodes to a corresponding preceding one of the odd nodes along the sequence, or a combination thereof.

12. The method of claim 11, wherein generating the second signal is based at least in part on the corresponding preceding one of the even nodes being an immediately preceding even node to the corresponding one of the even nodes, or the corresponding preceding one of the odd nodes being an immediately preceding odd node to the corresponding one of the even nodes, or both.

13. The method of claim 11, wherein the delay of the second signal relative to the first signal is based at least in part on the inverted signal corresponding to the one of the even nodes reducing a voltage at the corresponding previous one of the even nodes, or the inverted signal corresponding to the one of the odd nodes reducing a voltage at the corresponding previous one of the odd nodes, or a combination thereof.

14. The method of claim 11, further comprising:
generating the respective first inverted signal, generating the respective second inverted signal, or both via a respective tri-statable inverter.

15. The method of claim 14, wherein generating the respective first inverted signal, generating the respective second inverted signal, or both is based at least in part on applying a first voltage at a first input of the respective tri-state inverter and applying a second voltage at a second input of the respective tri-state inverter.

16. The method of claim 15, further comprising:
controlling a value of the delay relative to the first signal based at least in part on controlling a first value of the first voltage and controlling a second value of the second voltage.

17. The method of claim 11, wherein generating the second signal is based at least in part on an output of a last delay element along the sequence being coupled with an input of the last delay element via an even quantity of inverters.

18. A memory device, comprising:
one or more memory arrays;
a signal source associated with a first signal; and
a delay circuit configured to generate a second signal associated with accessing the one or more memory arrays and having a delay relative to the first signal, based at least in part on receiving the first signal from the signal source, the delay circuit comprising:
a plurality of delay elements coupled in series along a sequence of alternating odd nodes and even nodes between an input of the delay circuit and an output of the delay circuit;
one or more first feedback elements each configured to send an inverted first signal of a corresponding one of the even nodes to a corresponding preceding one of the even nodes along the sequence; and
one or more second feedback elements each configured to send an inverted second signal of a corresponding one of odd nodes to a corresponding preceding one of the odd nodes along the sequence.

19. The memory device of claim 18, wherein the delay is based at least in part on the inverted first signal corresponding to the one of the even nodes reducing a voltage at the corresponding previous one of the even nodes, or the inverted second signal corresponding to the one of the odd nodes reducing a voltage at the corresponding previous one of the odd nodes, or a combination thereof.

20. The memory device of claim 18, wherein:
at least one of the plurality of delay elements comprises a p-over-n inverter; and
at least one of the one or more first feedback elements, at least one of the one or more second feedback elements, or both comprises a tri-statable inverter.
